(19) United States
(12) Patent Application Publication
(10) Pub. No.: US 2026/0156966 A1
(43) Pub. Date: Jun. 4, 2026

(54) METHOD FOR MANUFACTURING SEMICONDUCTOR DEVICE

(71) Applicant: CANON KABUSHIKI KAISHA, Tokyo (JP)

(72) Inventors: KOJI HARA, Chiba (JP); AKIRA MATSUZAKI, Kanagawa (JP); MAYU ISHIKAWA, Kanagawa (JP)

(21) Appl. No.: 19/391,621

(22) Filed: Nov. 17, 2025

(30) Foreign Application Priority Data
Nov. 29, 2024 (JP) 2024-208061

(51) Int. Cl. H10F 77/40

(52) U.S. Cl. CPC H10F 77/413

(57) ABSTRACT

A method for manufacturing a semiconductor device. The semiconductor device includes a substrate having a first surface and a second surface opposing the first surface and including a photoelectric conversion element configured to generate an electric charge according to light incident from the first surface, and an insulating film disposed on the first surface. The method includes preparing the substrate with the insulating film provided on the first surface, the insulating film having an opening at a position at least partially overlapping the photoelectric conversion element in a plan view of the first surface, and forming a first film having a flat upper surface by applying a precursor on the substrate in such a manner that an application amount of the precursor is larger at a portion above the opening than at another portion. The forming of the first film includes bringing a superstrate into contact with the precursor.

### BACKGROUND

### Field of the Technology

The present disclosure relates to a method for manufacturing a semiconductor device.

### Description of the Related Art

Japanese Patent Laid-Open No. 2012-182427 describes a semiconductor device having a waveguide.

A method for forming the waveguide described in Japanese Patent Laid-Open No. 2012-182427 includes a process of planarization by filling large openings with a high refractive-index material and removing portions other than the openings. The removal is repeated a plurality of times for the planarization. Since the planarization is affected by a layout density of the openings, it has been difficult to easily acquire a high degree of flatness.

### SUMMARY

The present disclosure is directed to providing a method for facilitating formation of a waveguide.

A method for manufacturing a semiconductor device, the semiconductor device including a substrate having a first surface and a second surface opposing the first surface and including a photoelectric conversion element configured to generate an electric charge according to light incident from the first surface, and an insulating film disposed on the first surface, the method including preparing the substrate with the insulating film provided on the first surface, the insulating film having an opening at a position at least partially overlapping the photoelectric conversion element in a plan view of the first surface, and forming a first film having a flat upper surface by applying a precursor on the substrate in such a manner that an application amount of the precursor is larger at a portion above the opening than at another portion, wherein the forming of the first film includes bringing a superstrate into contact with the precursor.

Features of the present disclosure will become apparent from the following description of embodiments with reference to the attached drawings. The following description of embodiments is described by way of example.

### BRIEF DESCRIPTION OF THE DRAWINGS

FIG. 1 is a schematic view illustrating a configuration of a planarization apparatus.

FIGS. 2A, 2B, and 2C are schematic views illustrating planarization processing.

FIGS. 3A and 3B are schematic views illustrating a method for manufacturing a semiconductor device according to a first embodiment.

FIGS. 4A and 4B are schematic views illustrating the method for manufacturing the semiconductor device according to the first embodiment.

FIG. 5 is a schematic view illustrating a method for manufacturing a semiconductor device according to a second embodiment.

FIGS. 6A, 6B, and 6C are schematic views each illustrating an application example of a semiconductor device according to a third embodiment.

### DESCRIPTION OF THE EMBODIMENTS

Hereinafter, embodiments will be described with reference to the drawings. The following embodiments are not intended to limit the disclosure as defined by the claims. Although multiple features are described in the embodiments, not all of these features are necessarily essential to the disclosure, and the features may be combined arbitrarily. Furthermore, in the accompanying drawings, identical or similar components are denoted by the same reference numerals, and the redundant descriptions may be omitted.

Hereinafter, embodiments of the present disclosure will be described in detail with reference to the drawings. In the following description, terms indicating specific directions or positions (e.g., “upper,” “lower,” “right,” “left,” and other terms including these) may be used, as necessary. These terms are employed to facilitate understanding of the embodiments with reference to the drawings, and are not intended to limit the technical scope of the present disclosure based on their literal meanings.

In the present specification, a “plan view” refers to a view in a direction perpendicular to the upper surface of a semiconductor substrate. A “cross-sectional view” refers to a view of a surface in a direction perpendicular to the upper surface of the semiconductor substrate. In cases where the upper surface of the semiconductor substrate is microscopically rough, the plan view is defined based on the macroscopically observed upper surface. The upper surface of the semiconductor substrate refers to the surface on which an element, such as a transistor gate, is formed, or the surface having contact regions with a contact plug.

Expressions such as “A or B,” “at least one of A and B,” “at least one of A and/or B,” and “one or more of A and/or B” are understood to include all possible combinations of the listed items unless explicitly defined otherwise. That is, such expressions disclose all cases including at least one of A, at least one of B, and at least one of both A and B. This interpretation similarly applies to combinations involving three or more elements.

### FIRST EMBODIMENT

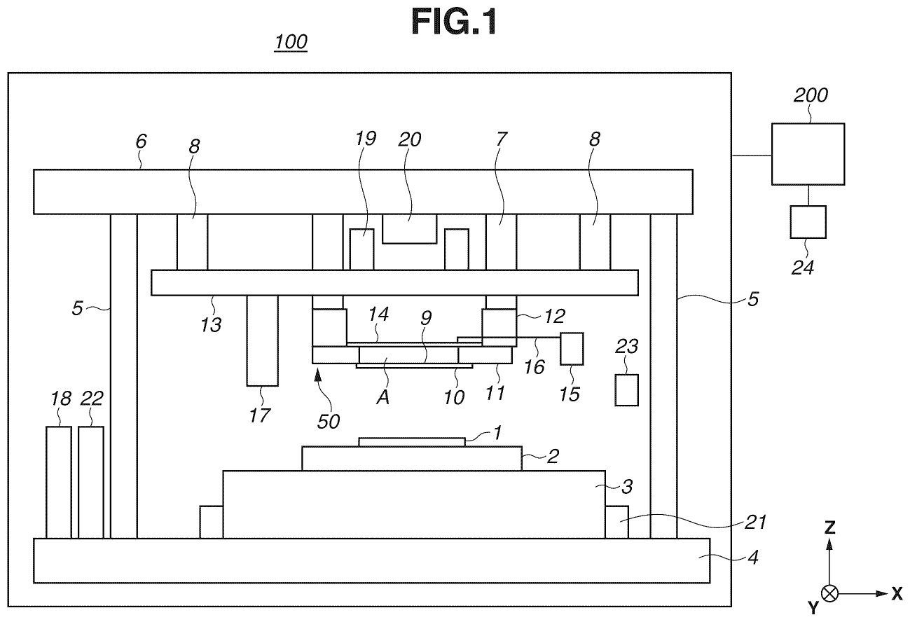

FIG. 1 is a schematic view illustrating a configuration of a planarization apparatus 100 according to the present embodiment. Directions will be indicated in an XYZ coordinate system where a horizontal surface is defined as an XY plane. Generally, a substrate 1, which is a processing target, is placed on a substrate stage 3 in such a manner that a surface of the substrate 1 extends in parallel to the horizontal surface (the XY plane). Therefore, hereinafter, directions orthogonal to each other in a plane extending along the surface of the substrate 1 will be defined as an X-axis and a Y-axis, and a direction perpendicular to the X-axis and the Y-axis will be defined as a Z-axis. Hereinafter, directions parallel to the X-axis, the Y-axis, and the Z-axis of the XYZ coordinate system will be referred to as an X-direction, a Y-direction, and a Z-direction, respectively, and a rotational direction around the X-axis, a rotational direction around the Y-axis, and a rotational direction around the Z-axis will be referred to as a θX-direction, a θY-direction, and a θZ-direction, respectively. As will be described below, the substrate 1 may be a member to which a semiconductor process can be applied, such as a semiconductor wafer, a semiconductor wafer with a wiring structure formed thereon, a glass substrate with an element formed thereon, or a metal substrate.

Underlying patterns on substrates have an uneven profile due to a pattern formed in the previous process. Especially, with the recent trend toward multi-layered structures in memory elements, some process substrates have a step height as large as approximately 100 nanometers (nm). A step height due to gradual warpage across the entire substrate can be corrected by a focus tracking function of a scan exposure apparatus that is used in a photolithographic process. However, fine unevenness with such a small pitch that fall within an exposure slit area of the exposure apparatus may fall outside the depth of focus (DOF) of the exposure apparatus. Conventionally, methods for forming a planarization layer or applying planarization processing, such as Spin On Carbon (SOC) and Chemical Mechanical Polishing (CMP), have been used as methods for planarizing the underlying patterns of the substrates. However, a disadvantage arises in which a sufficient planarization performance cannot be acquired by the conventional techniques. For example, the manufacturing process has advanced to new technology nodes, such as 22 nm, 16 nm, 14 nm, and 10 nm. Even though planarization layers sufficient for practical use have been acquired for nodes one generation ago, these planarization layers may no longer be adequate for practical use for nodes after that. Examples thereof include when the surface unevenness of planarization layers that used to be allowed for previous nodes is no longer allowed for next nodes. While CMP requires high process cost and is applicable to only limited processes, the unevenness difference on the underlying layers due to the multi-layered structures tends to be further increasing in the future.

To address this disadvantage, a planarization apparatus that planarizes a substrate using an imprinting technique has been studied. The planarization apparatus planarizes a local region in the substrate surface or the entire surface of the substrate by bringing a planarization surface of a member or a member having no pattern formed thereon (flat template) into contact with an uncured composition that has been previously supplied onto the substrate. After that, the composition is cured while the composition and the flat template are maintained to be in contact with each other, and the flat template is separated from the cured composition.

As a result of the above-described process, the planarization layer is formed on the substrate. Since this planarization apparatus is not affected by the unevenness of the patterned surface of the substrate in contrast to a commonly-employed planarization method using an SOC sacrificial film, it is expected to achieve improved planarization accuracy compared to existing methods.

The planarization apparatus 100 illustrated in FIG. 1 can be embodied by a molding apparatus that molds a composition on the substrate 1 using a plate (superstrate) 9, which is a pressing member. The planarization apparatus 100 forms a planarization layer using a material on the substrate 1 by curing the composition while the material on the substrate 1 and the plate 9 are in contact with each other, and separating the plate 9 from the cured composition.

The substrate 1 is a semiconductor, insulator, or metal substrate, and has a circular shape like a silicon wafer or a quartz wafer, or a square or rectangle like a (mother) glass for a flat panel display (FPD). The material of the substrate 1 can be a single-crystalline silicon wafer, but is not limited thereto. The material of the substrate 1 can be an elemental semiconductor or a compound semiconductor such as silicon, germanium, diamond, silicon carbide, silicon-germanium, gallium nitride, gallium arsenide, indium arsenide, or cadmium telluride. The material of the substrate 1 can be an inorganic insulator, such as silicon oxide, silicon nitride, aluminum oxide, or aluminum nitride. The material of the substrate 1 can be an organic insulator like polyimide, polyamide, or polycarbonate. The substrate 1 may be aluminum, a titanium-tungsten alloy, an aluminum-silicon alloy, or an aluminum-copper-silicon alloy. In other words, the substrate 1 can be made from one or a plurality of material(s) arbitrarily selected from the above-listed materials and the like. At least one layer of a semiconductor, insulator, or metal film may be formed on the surface of the substrate 1, and the surface of the substrate 1 can be a flat surface or a surface with unevenness formed thereon.

In addition, a substrate having an adhesion layer formed on the surface of the substrate by a surface treatment, such as a silane coupling treatment, a silazane treatment, or organic thin film deposition to improve adhesion to the composition may be used. The substrate 1 typically has a circular shape with a diameter of 300 millimeters (mm), but is not limited thereto.

The plate 9 can be made from a light-transmissive material in consideration of a light irradiation process. Examples of types of such a material include a light-transmissive inorganic material, such as glass or quartz, or a light-transmissive organic material, such as polymethyl methacrylate (PMMA) or polycarbonate resin. The plate 9 may be either a rigid plate or a flexible film. The surface of the plate 9 that comes in contact with the composition is flat. It is desirable that the plate 9 have a circular shape with a diameter larger than 300 mm and smaller than 500 mm, but the configurations is not limited thereto. It is also desirable that the thickness of the plate 9 be 0.25 mm or more and less than 2 mm, but the configuration is not limited thereto. In a case where the composition is a thermosetting material instead of a photo-curable material, the plate 9 does not need to be transparent and may be made from any material having the above-described properties.

The composition serves as a precursor that, upon curing, forms at least a part of a planarization film and is a curable composition that can be cured by exposure to light or thermal energy. The curable composition that can be cured by exposure to light or thermal energy can be a photo-curable composition that cures upon exposure to light, a thermosetting composition that cures upon exposure to thermal energy, or photothermally curable composition that cures upon exposure to light and thermal energy. Examples of the photo-curable composition include ultraviolet (UV) curable liquid. Examples of typical UV-curable liquid that can be used include a monomer, such as acrylate or methacrylate. The curable composition may also be referred to as a moldable material. Hereinafter, the moldable material may also be referred to as a “material” simply.

The planarization apparatus 100 includes, as illustrated in FIG. 1, a substrate chuck 2, the substrate stage 3, a base table 4, columns 5, a top plate 6, a guide bar 7, columns 8, a plate chuck 11, a head 12, and an alignment shelf 13. The planarization apparatus 100 further includes a pressure adjustment unit 15, a supply unit 17, a substrate conveyance unit 18, an alignment scope 19, a light source 20, a stage drive unit 21, a plate conveyance unit 22, a cleaning unit 23, an input unit 24, and a control unit 200. The substrate chuck 2 and the substrate stage 3 can move the substrate 1 while holding the substrate 1. The plate chuck 11 and the head 12 can move the plate 9 while holding the plate 9.

The substrate 1 is conveyed in from outside the planarization apparatus 100 by the substrate conveyance unit 18 including a conveyance hand or the like, and is held by the substrate chuck 2. The substrate stage 3 is supported by the base table 4, and is driven in the X-direction and the Y-direction to position the substrate 1 held by the substrate chuck 2 at a predetermined position. The stage drive unit 21 includes, for example, a linear motor or an air cylinder, and drives the substrate stage 3 at least in the X-direction and the Y-direction, and may have a function of driving the substrate stage 3 in directions of two or more axes (for example, six axial directions). The stage drive unit 21 may include a rotation mechanism and can rotationally drive the substrate chuck 2 or the substrate stage 3 in the θZ-direction.

The plate 9 serving as the pressing member is conveyed in from outside the planarization apparatus 100 by the plate conveyance unit 22 including a conveyance hand or the like, and is held by the plate chuck 11. The plate 9 has, for example, a circular or quadrilateral outer shape, and has a first surface including a flat surface 10, which comes into contact with the material placed on the substrate 1, and a second surface opposite from this first surface. In the present embodiment, the flat surface 10 has a size equal to or larger than the substrate 1. The plate chuck 11 is supported by the head 12 and can have a function of correcting the position of the plate 9 in the θZ-direction (an inclination around the Z-axis). Both the plate chuck 11 and the head 12 include an opening that allows light (an ultraviolet ray) emitted from the light source 20 via a collimator lens to pass through. The plate chuck 11 functions as a holding unit that mechanically holds the plate 9. For example, the plate chuck 11 holds the plate 9 by attracting the second surface of the plate 9 with this second surface facing upward. The head 12 mechanically holds the plate chuck 11. The plate chuck 11 and the head 12 are included in a formation unit 50 that performs processing for forming a planarization film. The head 12 includes a drive mechanism (not illustrated) for positioning a distance between the substrate 1 and the plate 9 when the plate 9 is brought into and out of contact with the material on the substrate 1, and moves the plate 9 in the Z-direction. The drive mechanism of the head 12 may be configured using an actuator, such as a linear motor, an air cylinder, or a voice coil motor. A load cell for measuring a pressing force (an imprinting force) of the plate 9 against the material on the substrate 1 may be disposed on the plate chuck 11 or the head 12. A plate deformation mechanism (a plate deformation unit) includes a sealing member 14 sealing a spatial region A, which is an inner space defined by the inner surface of the plate chuck 11 and the plate 9, into a sealed cavity. The plate deformation mechanism includes the pressure adjustment unit 15 disposed outside the plate chuck 11 and configured to adjust the pressure in the spatial region A. The sealing member 14 is made of a light-transmissive flat plate member, such as quartz glass, and includes, at a portion thereof, a connection port (not illustrated) of a pipe 16 connected to the pressure adjustment unit 15. The pressure adjustment unit 15 can increase the pressure within the spatial region A to enlarge an amount of deformation of the plate 9 protruding toward the substrate 1. The pressure adjustment unit 15 can reduce the pressure within the spatial region A to reduce the protruding deformation amount of the plate 9. The columns 5 supporting the top plate 6 are disposed on the base table 4. The guide bar 7 is suspended from the top plate 6, extends through the alignment shelf 13, and is fixed to the head 12. The alignment shelf 13 is suspended from the top plate 6 via the columns 8. The guide bar 7 extends through the alignment shelf 13. For example, a height measurement system (not illustrated) for measuring the height (the degree of flatness) of the substrate 1 held by the substrate chuck 2 using an oblique incidence image shift method is disposed on the alignment shelf 13.

The alignment scope 19 includes an optical system and an imaging system for an observation of a reference mark provided on the substrate stage 3 and an alignment mark provided on the plate 9. However, in a case where the alignment mark is not provided on the plate 9, the alignment scope 19 may be omitted. The alignment scope 19 is used in alignment in which the relative position between the reference mark provided on the substrate stage 3 and the alignment mark provided on the plate 9 are measured and a positional misalignment therebetween is corrected.

The supply unit 17 includes a dispenser having a discharge port (a nozzle) that discharges the material in an uncured state to the substrate 1, and supplies (applies) the material onto the substrate 1. The supply unit 17 employs, for example, a piezo jet method or a micro solenoid method, and can supply the material in an extremely small volume of approximately 1 picoliter (pL) onto the substrate 1 during scan driving of the substrate stage 3. The number of discharge ports in the supply unit 17 is not limited, and may be one (a single nozzle) or may be plural (for example, 100 or more). A linear nozzle array in one row or in a plurality of rows may be formed by a plurality of nozzles. Especially, a dispenser based on a method known as an inkjet head is desirable, because the dispenser can apply the material in the form of fine liquid droplets to the substrate 1. Especially, a piezo inkjet head including at least one discharge energy generator realized by a piezoelectric element for each discharge port can adjust the volume of the liquid droplet to be discharged, and thus is especially desirable.

The cleaning unit 23 cleans the plate 9 while the plate 9 is held by the plate chuck 11. In the present embodiment, the cleaning unit 23 removes the material attached to the plate 9, especially, the flat surface 10 by separating the plate 9 from the cured material on the substrate 1. The cleaning unit 23 may, for example, wipe off the material attached to the plate 9, or may remove the material attached to the plate 9 using UV irradiation, electrostatic discharge, wet cleaning, dry plasma cleaning, or the like.

The control unit 200 is configured as a computer device including a central processing unit (CPU) and a memory, and controls the entire operation of the planarization apparatus 100. The control unit 200 functions as a processing unit that performs planarization processing by integrally controlling each unit of the planarization apparatus 100. Here, the planarization processing refers to processing for planarizing the material by bringing the flat surface 10 of the plate 9 into contact with the material on the substrate 1 and causing the flat surface 10 to conform to the surface profile of the substrate 1. Generally, the planarization processing is performed on a lot basis, that is, for each of a plurality of substrates included in the same lot.

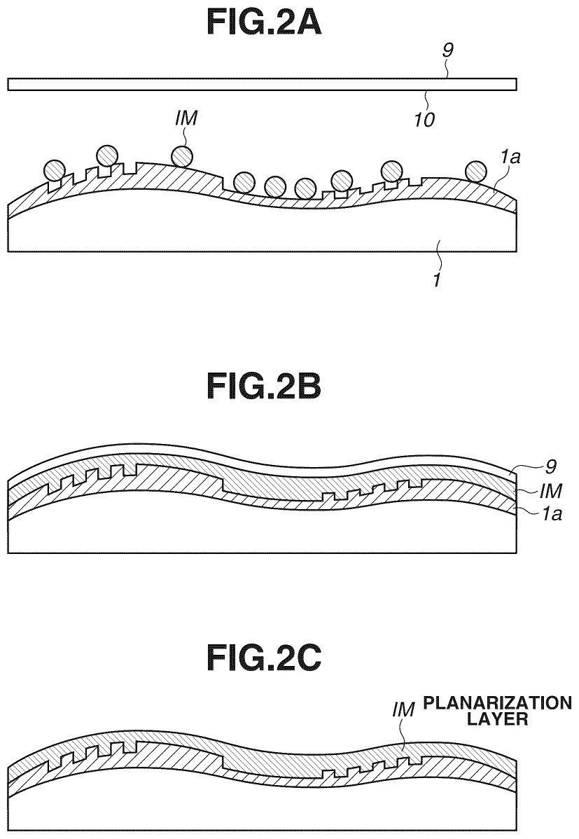

The planarization processing will be described with reference to FIGS. 2A, 2B, and 2C. First, a material IM is supplied by the supply unit 17 to the substrate 1, on which an underlying pattern 1a has been formed. FIG. 2A illustrates a state after the material IM is disposed on the substrate 1 and before the plate 9 is brought into contact with the material IM. As illustrated in FIG. 2B, the material IM on the substrate 1 and the flat surface 10 of the plate 9 are brought into contact with each other. The plate 9 presses the material IM, and the material IM spreads across the entire surface of the substrate 1. FIG. 2B illustrates a state in which the entire surface of the flat surface 10 of the plate 9 is in contact with the material IM on the substrate 1, and the flat surface 10 of the plate 9 conforms to the surface profile of the substrate 1. Then, in the state illustrated in FIG. 2B, the material IM on the substrate 1 is irradiated with light from the light source 20 via the plate 9, and thus, the material IM is cured. After that, the plate 9 is separated from the cured material IM on the substrate 1. As a result, a layer (a planarization layer) of the material IM having a uniform thickness over the entire surface of the substrate 1 is formed. FIG. 2C illustrates a state in which the planarization layer made of the material IM is formed on the substrate 1. Hereinafter, contact (adhesion) and separation between the flat surface 10 of the plate 9 and the material IM on the substrate 1 will be simply referred to as contact (adhesion) and separation between the plate 9 and the material IM on the substrate 1, respectively. Hereinafter, the material IM when being in a state supplied to the substrate 1 will also be referred to as a precursor, and after curing, will also be referred to as a film.

A method for manufacturing a product (a semiconductor device, a liquid crystal display device, a color filter, a micro electro mechanical system (MEMS), or the like) using the planarization apparatus 100 will be described. This manufacturing method includes a process of planarizing a composition by bringing the composition disposed on a substrate (a wafer, a glass substrate, or the like) into contact with a mold, a process of curing the composition, and a process of separating the composition and the mold by using the above-described planarization apparatus 100. As a result, a planarization film is formed on the substrate. Then, the product is manufactured by processing, such as formation of a pattern (patterning) using a lithography apparatus on the substrate with the planarization film formed thereon, and applying another known processing process to the processed substrate. Examples of the other known process include etching, a removal of a resist, dicing, bonding, and packaging. According to the present manufacturing method, a product of higher quality can be manufactured compared to a case using conventional methods.

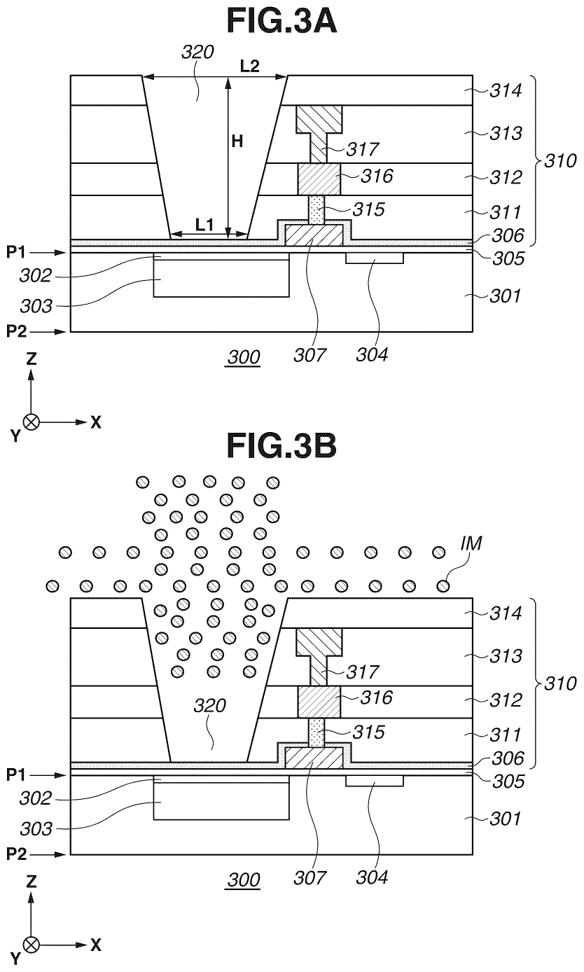

In the following description, the present manufacturing method will be described citing an example using a semiconductor device as a specific product. The semiconductor device may be, for example, a photoelectric conversion sensor. FIGS. 3A and 3B are schematic views illustrating a method for manufacturing the semiconductor device according to the present embodiment.

FIG. 3A illustrates a state in which an opening for a waveguide is formed after a wiring structure including a wiring and an interlayer insulation film has been formed. A semiconductor device 300 includes a semiconductor layer 301, a first insulating film 305, a second insulating film 306, and a wiring structure 310. The semiconductor layer 301 is made of, for example, a silicon single-crystal substrate, and includes a first surface P1 and a second surface P2 opposing the first surface P1. The first surface P1 is the upper surface of the semiconductor layer 301, and the second surface P2 is the lower surface of the semiconductor layer 301. A first semiconductor region 302, a second semiconductor region 303, and a third semiconductor region 304 are disposed in the semiconductor layer 301. For example, the first semiconductor region 302 is a P-type semiconductor region, and the second semiconductor region 303 is an N-type semiconductor region. The first semiconductor region 302 and the second semiconductor region 303 can constitute a photoelectric conversion element. The third semiconductor region 304 is an N-type region, and can constitute a transfer transistor together with a gate electrode 307. The photoelectric conversion element generates electric charges according to light incident from the first surface P1, and the transfer transistor transfers the electric charges from the photoelectric conversion element to a not-illustrated floating diffusion region. A signal based on the electric charge amount transferred to the floating diffusion region is output to a not-illustrated column circuit by an output circuit including a not-illustrated amplification transistor. This column circuit performs various processing, such as an analog-to-digital (AD) conversion processing for converting the input signal into a digital signal, and processing for reducing a noise component. Then, the digital signal is sequentially read out from a plurality of column circuits. Accordingly, the semiconductor device 300 according to the present embodiment can generate the signal based on the electric charges incident to the photoelectric conversion element. The first insulating film 305 may be a gate insulating film disposed between the semiconductor layer 301 and the gate electrode 307. The second insulating film 306 is, for example, a silicon nitride film, and can function as an etching stop film during contact formation. The wiring structure 310 includes a third insulating film 311, a fourth insulating film 312, a fifth insulating film 313, a sixth insulating film 314, a contact plug 315, a first wiring 316, and a second wiring 317. The contact plug 315, the first wiring 316, and the second wiring 317 are conductors that form an electric path. For example, the first wiring 316 has a single damascene structure, and the second wiring 317 has a dual damascene structure integrated with a via plug. The shapes of the insulating films and the wirings and the like are not limited to the examples described above. Up to this configuration, the semiconductor device can be formed by applying a general semiconductor device manufacturing. More specifically, the semiconductor layer 301 is prepared. The semiconductor regions are formed in the semiconductor layer 301. The first insulating film 305, the second insulating film 306, the gate electrode 307, and the like are formed on the semiconductor layer 301. Then, the insulating films and the conductors, such as the wirings, are appropriately formed to construct the wiring structure 310.

Then, the insulating film can be made of a single layer or multiple layers of any insulator material, such as silicon oxide, silicon oxynitride, silicon nitride, silicon oxycarbide, spin-on-glass (SOG), or a low dielectric material. The contact plug 315 can be made from a conductor material containing barrier metal, such as titan or titan nitride, and embedded metal, such as tungsten. The first wiring 316 and the second wiring 317 can be made from a conductor material containing aluminum, copper, or the like. The wiring layer and the plug can be formed by depositing a conductive film made pf a conductive material and removing excess portions of the conductive film.

After that, an opening 320 is formed by partially removing the third insulating film 311, the fourth insulating film 312, the fifth insulating film 313, and the sixth insulating film 314 using etching. In a plan view with respect to the first surface P1, the opening 320 may be formed at a position at least partially overlapping the photoelectric conversion element. In the plan view with respect to the first surface P1, the opening 320 may have a circular shape. For example, the opening 320 may be circular at a position at the same depth as the upper surface of the sixth insulating film 314, and the opening 320 may be circular at a position at the same depth as the upper surface of the second insulating film 306. As illustrated in FIG. 3A, the side surface of the opening 320 may have a taper shape extending from the upper portion of the wiring structure 310 to the semiconductor layer 301. A width L1 of the lower portion of the opening 320 and a width L2 of the upper portion of the opening 320 satisfy L1<L2. Desirably, the width L2 of the upper portion of the opening 320 is in a range of 50 nm to 100 nm, and a depth H of the opening 320 is in a range of 100 nm to 200 nm. It is also desirable that H/L2≤2 be satisfied.

A core (a high refractive index portion) of the waveguide is formed in the opening 320. First, as illustrated in FIG. 3B, the precursor (the material IM) in the form of liquid of the material capable of serving as the core is applied in accordance with a predetermined application amount determined such that the material IM is concentrated in a portion where the opening 320 is present and less in the other portions. Then, the flat surface 10 of the plate 9 illustrated in FIG. 2 is pressed against the material IM, and the material IM is cured. After that, the plate 9 is separated from the cured material IM on the semiconductor layer 301. Here, the material IM may be, for example, a precursor of energy-curable resin or a precursor of SOC.

On the opening 320 formed in advance, the uncured material is applied using the inkjet head equipped with the piezoelectric element as the discharge actuator. More specifically, liquid droplets are introduced into the interior of the opening 320 by injecting a liquid droplet from above the opening 320 a plurality of times (N+1 times or more per unit area, and N is a natural number). This process is achieved by injecting a liquid droplet N times per unit area on the flat surface of the wiring structure 310 other than the portion on the opening 320. Such a number of times of liquid droplet application can be determined according to a formation pattern of the opening 320. More specifically, the liquid droplets are applied while the relative position between the discharge port and the substrate is changed, according to a pattern map in which the number (or the amount) of liquid droplets applied onto the substrate and the application position in the upper surface have been determined based on pattern data of a resist mask for forming the opening 320.

The configuration of the semiconductor device 300 illustrated in FIG. 3A may be repeated in the in-plane direction (the X-direction or the Y-direction) of the semiconductor layer 301. In this case, the amount of the precursor to be applied at a portion above each opening 320 is larger than the amount of the precursor to be applied at the portion above the area between adjacent openings 320.

It is not necessary to completely fill the interior of the opening 320 with the liquid droplets. For example, a part of the opening 320 on the photoelectric conversion portion side may be formed by the thermal nitridation method, the thermal oxidation method, the sputtering method, the chemical vapor deposition (CVD) method, or the like, and then inject a liquid droplet a plurality of times into the remaining portion of the opening 320.

As the apparatus used for curing, an exposure apparatus can be employed. The exposure apparatus may be an argon fluoride (ArF) immersion exposure apparatus, an ArF dry exposure apparatus, or a krypton fluoride (KrF) exposure apparatus. The exposure amount thereof may also be adjusted according to the pattern of the opening 320.

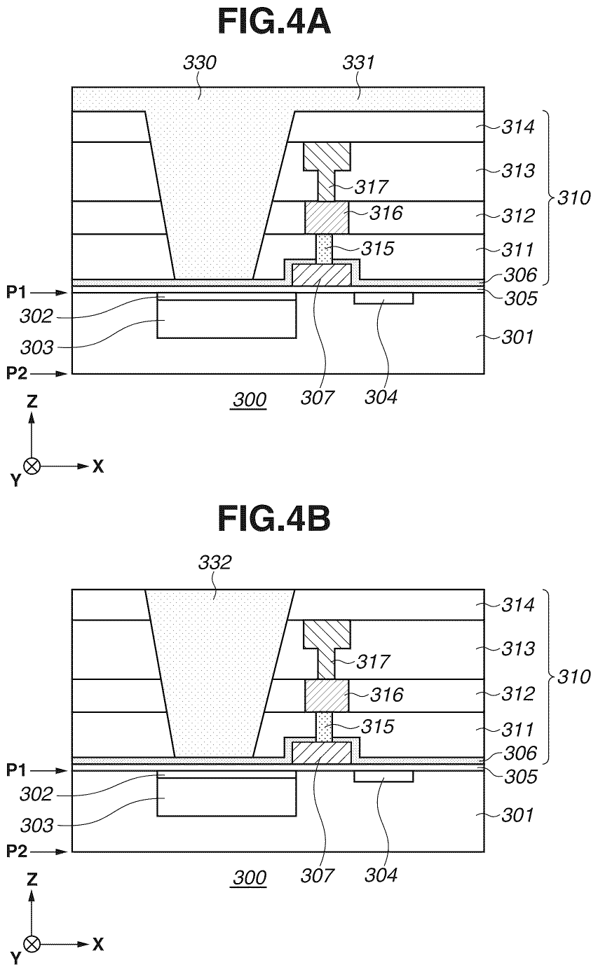

The core (a first film) as illustrated in FIG. 4A is formed by the above-mentioned formation method. The core includes a first portion 330 located inside the opening 320, and a second portion 331 located on the sixth insulating film 314. By using the plate 9 according to the present embodiment, the first portion 330 and the second portion 331 can have flat surfaces. The use of the plate 9 according to the present embodiment easily facilitates achieving a uniform film thickness in the second portion 331.

As illustrated in FIG. 4B, the second portion 331 may be removed after the process illustrated in FIG. 4A.

According to the method detailed above, it is possible to reduce the process for forming the core of the waveguide. Furthermore, since the planarization processing does not depend on the layout density of openings, excellent flatness can be achieved, for example, and thus the manufacturing method according to the present embodiment facilitates easily forming of the waveguide.

The material IM does not necessarily have to be a high refractive index material. This is because an appropriate waveguide can be realized by providing an opening extending through the plurality of insulating films and forming a uniform member. Especially, when a low dielectric material is used as the insulating film in the wiring structure 310, a disadvantage of a low optical transmittance of the film or occurrence of reflection due to a large refractive index difference between the insulating films may arise. In such a case, the formation of a uniform member can result in an appropriate waveguide. Moreover, it is further desirable that the member be a light-transmissive member.

In the present embodiment, when the material IM is applied, the inkjet head is controlled, in such a manner that more liquid droplets are discharged at the portion above the opening 320 than at the portions above other areas where the opening 320 is not provided. However, the present disclosure is not limited to this configuration. For example, when the material IM is applied, the inkjet head may be controlled in such a manner that liquid droplets are applied uniformly toward both the area where the opening 320 is disposed, and the area excluding the area where the opening 320 is provided. After that, the plate 9 in flat form is brought into contact with the material IM. Even by this method, the amount of the material IM located on the opening 320 can be made larger than the material IM located on the portions other than the portion where the opening 320 is provided. Such a method is also included in the process of applying the precursor in such a manner that the amount applied at the portion above the opening 320 is larger than the amount applied at the other portions.

### SECOND EMBODIMENT

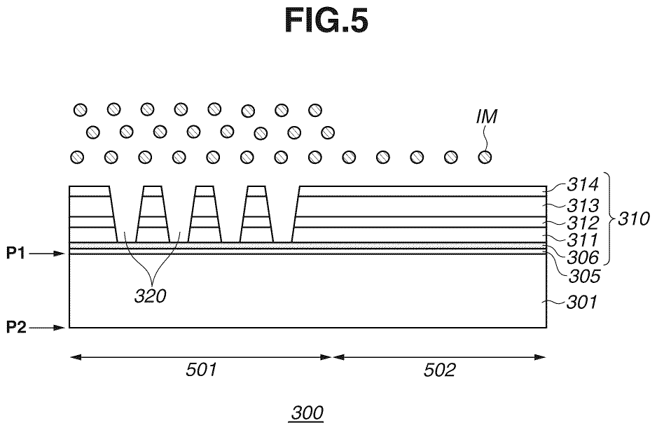

A method for manufacturing a semiconductor device according to a second embodiment will be described. FIG. 5 is a schematic view illustrating a method for manufacturing a semiconductor device according to the second embodiment. In the following description, the present embodiment will be described, omitting the detailed descriptions of configurations and processes similar to FIGS. 3A and 3B, and 4A and 4B.

As illustrated in FIG. 5, a semiconductor device 300 includes a pixel array region 501 (a first region) where a plurality of pixels is disposed, and a peripheral region 502 (a second region) where no pixel is disposed. Each of the plurality of pixels includes a photoelectric conversion element. In the plan view with respect to the first surface P1, in the pixel array region 501, a plurality of openings 320 may be formed at respective positions at least partially overlapping the plurality of photoelectric conversion elements. The peripheral region 502 is disposed between the pixel array region 501 and an end portion of the semiconductor layer 301 (the substrate).

The area density of the precursor (the material IM) in the form of liquid of the material capable of serving as the core, which is disposed on the wiring structure 310, is adjusted between the pixel array region 501 and the peripheral region 502. More specifically, as illustrated in FIG. 5, the material IM is applied in accordance with the predetermined application amount determined such that more material IM is applied to the pixel array region 501 where the openings 320 are formed, and less material IM is applied to the peripheral region 502 where the openings 320 are not formed. Then, the flat surface 10 of the plate 9 illustrated in FIG. 2 is pressed against the material IM, and the material IM is cured. After that, the plate 9 is separated from the cured material IM on the semiconductor layer 301. Here, the material IM may be, for example, a precursor of energy-curable resin or a precursor of SOC.

The uncured material is applied at the portion above the pixel array region 501 using the inkjet head equipped with the piezoelectric element serving as the discharge actuator. More specifically, this method can be realized by injecting a liquid droplet at the portion above the pixel array region 501 a plurality of times (N+1 times or more per unit area, and N is a natural number), and injecting a liquid droplet on the peripheral region 502 N times per unit area. Such a number of times of liquid droplet application can be determined according to a formation pattern of the openings 320. More specifically, the liquid droplets are applied while the relative position between the discharge port and the substrate is changed according to a pattern map in which the number (or the amount) of liquid droplets to be applied onto the substrate and the application position in the upper surface are determined based on pattern data of a resist mask for forming the openings 320.

As the apparatus used for curing, for example, an exposure apparatus may be employed. The exposure apparatus may be an ArF immersion exposure apparatus, an ArF dry exposure apparatus, or a KrF exposure apparatus. The exposure amount may also be adjusted according to the pattern of the openings 320.

According to the method detailed above, it is possible to reduce the process for forming the core of the waveguide. Furthermore, since the planarization processing does not depend on the layout density of the openings, excellent flatness can be achieved, for example, and thus the manufacturing method according to the present embodiment facilitates easily forming of the waveguide.

As described above, the manufacturing method according to the present embodiment is particularly effective for a semiconductor device, such as photoelectric conversion sensors in which pattern density may vary between the pixel region and other regions.

In addition to a photoelectric conversion sensor, the present manufacturing method may also be applicable to other devices in which pattern density may vary, such as display devices and memory devices.

The material IM does not have to be a high refractive index material. This is because an appropriate waveguide can be realized by providing an opening extending through the plurality of insulating films and forming a uniform member. Especially, when a low dielectric material is used as the insulating film, a disadvantage of a low optical transmittance of the film or occurrence of reflection due to a large refractive index difference between the insulating films may arise. In such a case, the formation of a uniform member can result in an appropriate waveguide. In this case, it is further desirable that the member be a light-transmissive member.

In the present embodiment, the inkjet head is controlled when the material IM is applied, so that more liquid droplets are discharged at the portion above the pixel array region 501 than at the portion above the peripheral region 502. However, the manufacturing method is not limited to this example. For example, during application of the material IM, liquid droplets may be uniformly applied to both the pixel array region 501 and the peripheral region 502. After that, the plate 9 in a flat form is brought into contact with the material IM. Even by this method, the amount of the material IM on the pixel array region 501 can be made larger than the material IM on the peripheral region 502. Such a method is also included in the process of applying the precursor in such a manner that the amount applied on the pixel array region 501 is larger than the amount applied on the peripheral region 502.

### THIRD EMBODIMENT

A third embodiment will be described regarding an application example using the semiconductor device manufactured by the manufacturing method according to any of the first and second embodiments. A semiconductor device 910 is, for example, a photoelectric conversion sensor.

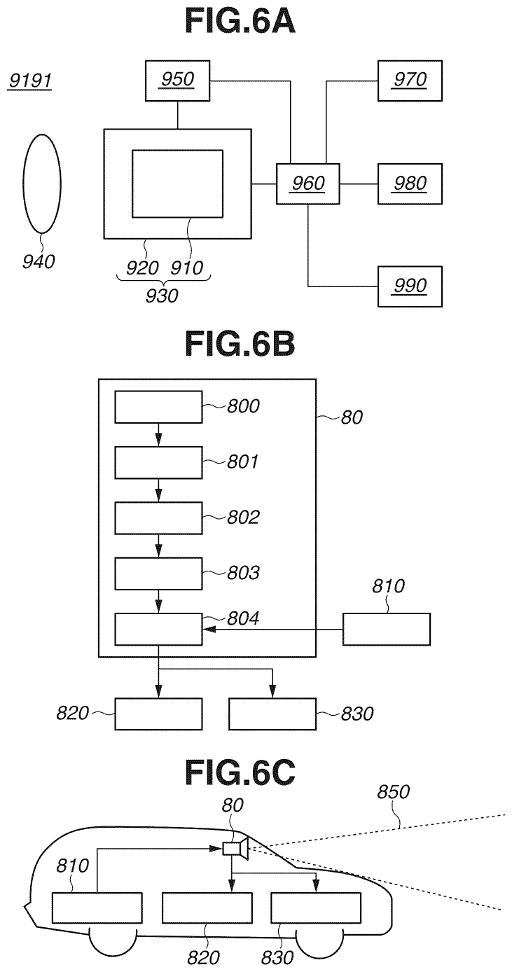

FIG. 6A is a schematic view illustrating an apparatus 9191, which is the application example. The apparatus 9191 includes a semiconductor apparatus 930. The semiconductor apparatus 930 includes a semiconductor device 910 and a package 920 including the semiconductor device 910. The semiconductor device 910 can be manufactured by a manufacturing method according to another embodiment. The package 920 may include a substrate on which the semiconductor device 910 is fixed, and a cover member, such as glass, facing the semiconductor device 910. The package 920 can further include a bonding member, such as a bonding wire and a bump connecting a terminal provided on the substrate and a terminal provided on the semiconductor device 910.

The apparatus 9191 can include at least any of an optical apparatus 940, a control apparatus 950, a processing apparatus 960, a display apparatus 970, a storage apparatus 980, and a mechanical apparatus 990. The optical apparatus 940 corresponds to the semiconductor apparatus 930. The optical apparatus 940 is, for example, a lens, a shutter, and a mirror, and includes an optical system that guides light to the semiconductor apparatus 930. The control apparatus 950 controls the semiconductor apparatus 930. The control apparatus 950 is, for example, a semiconductor apparatus such as an application specific integrated circuit (ASIC).

The processing apparatus 960 processes a signal output from the semiconductor apparatus 930. The processing apparatus 960 is a semiconductor apparatus, such as a central processing unit (CPU) or an ASIC, configured to constitute an analog front end (AFE) or a digital front end (DFE). The display apparatus 970 is an electro-luminescence (EL) display apparatus or a liquid crystal display apparatus that displays information (an image) acquired by the semiconductor apparatus 930. The storage apparatus 980 is a magnetic device or a semiconductor device that stores the information (the image) acquired by the semiconductor apparatus 930. The storage apparatus 980 is a volatile memory, such as a static random-access memory (SRAM) or a dynamic random-access memory (DRAM), or a nonvolatile memory, such as a flash memory or a hard disk drive.

The mechanical apparatus 990 includes a movable unit or a drive unit, such as a motor or an engine. The apparatus 9191, for example, displays the signal output from the semiconductor apparatus 930 on the display apparatus 970 or transmits the signal to outside using a communication apparatus (not illustrated) included in the apparatus 9191. Therefore, it is desirable that the apparatus 9191 further include the storage apparatus 980 and the processing apparatus 960 separately from a storage circuit and an arithmetic circuit included in the semiconductor apparatus 930. The mechanical apparatus 990 may be controlled based on signals output from the semiconductor apparatus 930.

The apparatus 9191 is applicable to an electronic apparatus, such as an information terminal having an imaging function (for example, a smart-phone and a wearable terminal) or a camera (for example, an interchangeable-lens camera, a compact camera, a video camera, or a monitoring camera). The mechanical apparatus 990 in the camera can drive a component of the optical apparatus 940 for zooming, focusing, and a shutter operation. Alternatively, the mechanical apparatus 990 in the camera can move the semiconductor apparatus 930 for a vibration damping operation.

The apparatus 9191 may also be a transportation apparatus, such as a vehicle, a ship, or an aircraft. The mechanical apparatus 990 in the transportation apparatus can be used as a movement apparatus. When the apparatus 9191 is used as the transportation apparatus, it is particularly applicable for transporting the semiconductor apparatus 930 or for assisting and/or automating driving (piloting) using the imaging function. The processing apparatus 960 for assisting and/or automating driving (piloting) may perform processing to operate the mechanical apparatus 990 serving as the movement apparatus, based on the information acquired by the semiconductor apparatus 930. Alternatively, the apparatus 9191 may be a medical appliance, such as an endoscope, a measurement instrument, such as a ranging sensor, an analytical instrument, such as an electronic microscope, an office appliance, such as a copying machine, or industrial equipment, such as a robot.

According to the above-described embodiment, desirable pixel characteristics can be obtained. Therefore, the value of the semiconductor apparatus can be enhanced. Enhancing the value described here refers to at least any of adding functionality, improving performance, enhancing characteristics, increasing reliability, improving manufacturing yield, reducing the environmental impact, lowering cost, miniaturization, and weight reduction.

Therefore, by employing the semiconductor apparatus 930 according to the present embodiment in the apparatus 9191, the value of the apparatus 9191 can also be enhanced. For example, an excellent performance can be acquired when the semiconductor apparatus 930 is mounted on the transportation apparatus and captures an image outside the transportation apparatus or measures the external environment. Therefore, it is advantageous to determine to mount the semiconductor apparatus 930 according to the present embodiment onto the transportation apparatus when manufacturing or selling the transportation apparatus in terms of enhancing the performance of the transportation apparatus itself. Especially, it is desirable that the semiconductor apparatus 930 is used for such a transportation apparatus that performs driving assistance and/or autonomous driving based on information acquired by the semiconductor apparatus.

A movable object will be described as another application example. FIG. 6B illustrates an example of a photoelectric conversion system 80 related to an on-vehicle camera. The photoelectric conversion system 80 includes a semiconductor device 800. The semiconductor device 800 is, for example, a photoelectric conversion device (an imaging device). The photoelectric conversion system 80 includes an image processing unit 801, which performs image processing on a plurality of pieces of image data acquired by the semiconductor device 800, and a parallax acquisition unit 802, which calculates parallax (a phase difference between parallax images) from the plurality of pieces of image data acquired by the photoelectric conversion system 80.

The photoelectric conversion system 80 may include, for example, a not-illustrated optical system that guides light to the semiconductor device 800, such as a lens, a shutter, and a mirror. A plurality of photoelectric conversion portions substantially conjugate with a pupil of the optical system may be disposed at a pixel included in the semiconductor device 800. For example, the plurality of photoelectric conversion portions substantially conjugate with the pupil may be disposed to correspond to a single microlens. The plurality of photoelectric conversion portions receives light fluxes transmitted through positions different from each other in the pupil of the optical system, whereby the semiconductor device 800 outputs image data corresponding to the light fluxes transmitted through the different positions. Then, the parallax acquisition unit 802 may calculate parallax using the output image data. The photoelectric conversion system 80 includes a distance acquisition unit 803, which calculates a distance to a target based on the calculated parallax, and a collision determination unit 804, which determines whether there is a collision possibility based on the calculated distance. Here, the parallax acquisition unit 802 and the distance acquisition unit 803 are examples of a distance information acquisition unit that acquires distance information to a target object. In other words, the distance information refers to information regarding parallax, a defocus amount, a distance to a target object, and/or the like. The collision determination unit 804 may determine the collision possibility by using any of these pieces of distance information. The distance information may be acquired by Time of Flight (ToF). The distance information acquisition unit may be realized by dedicated hardware or may be realized by a software module. The distance information acquisition unit may be realized by a field programmable gate array (FPGA), an ASIC, or the like, or may be realized by a combination of them.

The photoelectric conversion system 80 is connected to a vehicle information acquisition apparatus 810, and can acquire vehicle information, such as a vehicle speed, a yaw rate, and a steering angle. The photoelectric conversion system 80 is connected to a control electronic control unit (ECU) 820, which is a control apparatus that outputs a control signal for generating a braking force to the vehicle, based on a result of the determination by the collision determination unit 804. The photoelectric conversion system 80 is also connected to a warning apparatus 830, which issues a warning to a driver based on the result of a determination by the collision determination unit 804. For example, when the collision possibility is high as a result of the determination by the collision determination unit 804, the control ECU 820 controls the vehicle so as to avoid the collision or reduce damage by, for example, braking the vehicle, releasing an accelerator, and/or reducing an engine output. The warning apparatus 830 warns the user by, for example, producing a warning sound or the like, displaying warning information on a screen of a car navigation system or the like, and/or vibrating a seat belt or a steering wheel.

In the present embodiment, surroundings of the vehicle, such as the area ahead of or behind the vehicle, are imaged by the photoelectric conversion system 80. FIG. 6C illustrates the photoelectric conversion system 80 in a case of capturing an image ahead of the vehicle (an imaging range 850). The vehicle information acquisition apparatus 810 transmits an instruction to the photoelectric conversion system 80 or the semiconductor device 800. With this configuration, the distance can be measured with further improved accuracy.

In the above description, the photoelectric conversion system 80 has been described referring to the example that performs control to prevent the vehicle from colliding with another vehicle, and is also applicable to control for autonomous driving of the vehicle to cause the vehicle to follow another vehicle, control for autonomous driving of the vehicle to prevent the vehicle from departing from a traffic lane, or the like. Further, the photoelectric conversion system 80 is applicable to not only the vehicle, such as the automobile, but also a movable object (a movable apparatus) such as a ship, an airplane, or an industrial robot. This movable object includes one or both of a driving force generation unit that generates a driving force to be mainly used to move this movable object, and a rotational body mainly used to move this movable object. The driving force generation unit can be an engine, a motor, or the like. The rotational body can be a tire, a wheel, a screw of a ship, a propeller, or the like. In addition, the photoelectric conversion system 80 is applicable to not only the movable object but also an apparatus broadly using object recognition, such as an intelligent transportation system (ITS).

The apparatus according to the present embodiment may be a transportation device such as a vehicle, a ship, or an aircraft. A mechanical device in the transportation device may be used as a moving device. The apparatus as a transportation device is suitably used for transporting semiconductor devices, or for assisting and/or automating driving (piloting) through imaging functions. A processing device for assisting and/or automating driving (piloting) may perform processing to operate the mechanical device as a moving device based on information obtained from the semiconductor device.

The present embodiment has been described citing the photoelectric conversion device as an example of the semiconductor device, but the semiconductor device may be another semiconductor device or may be both of them.

According to the present disclosure, formation of a waveguide can be facilitated.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2024-208061, filed Nov. 29, 2024, which is hereby incorporated by reference herein in its entirety.

What is claimed is:

1. A method for manufacturing a semiconductor device, the semiconductor device including:
a substrate having a first surface and a second surface opposing the first surface and including a photoelectric conversion element configured to generate an electric charge according to light incident from the first surface; and
an insulating film disposed on the first surface,
the method comprising:
preparing the substrate with the insulating film provided on the first surface, the insulating film having an opening at a position at least partially overlapping the photoelectric conversion element in a plan view of the first surface; and
forming a first film having a flat upper surface by applying a precursor on the substrate in such a manner that an application amount of the precursor is larger at a portion above the opening than at another portion,
wherein the forming of the first film includes bringing a superstrate into contact with the precursor.

2. The method for manufacturing the semiconductor device according to claim 1, wherein the forming the first film includes planarizing an upper surface of the precursor and curing the precursor in such a manner that the first film has a flat upper surface.

3. The method for manufacturing the semiconductor device according to claim 1, wherein the forming the first film includes curing the precursor while the superstrate is in contact with the precursor.

4. The method for manufacturing the semiconductor device according to claim 1, wherein the forming the first film includes applying the precursor in such a manner that the application amount of the precursor is larger at a portion above the opening than at a portion between a plurality of the openings.

5. The method for manufacturing the semiconductor device according to claim 1, wherein the first film includes a first portion disposed on the opening and a second portion disposed on the insulating film, and
wherein the method for manufacturing the semiconductor device further includes removing the second portion.

6. The method for manufacturing the semiconductor device according to claim 1, wherein the forming the first film includes forming the first film from a material different from the insulating film.

7. The method for manufacturing the semiconductor device according to claim 1, wherein the semiconductor device includes a transfer transistor configured to transfer the electric charge from the photoelectric conversion element, and
wherein in the plan view of the first surface, the transfer transistor includes a gate electrode arranged between a plurality of the openings.

8. The method for manufacturing the semiconductor device according to claim 1, wherein the semiconductor device includes a transfer transistor configured to transfer the electric charge from the photoelectric conversion element, and
wherein the first surface is arranged between a gate electrode included in the transfer transistor and the second surface.

9. The method for manufacturing the semiconductor device according to claim 1, wherein the substrate includes a first region where a plurality of the photoelectric conversion elements is disposed, and a second region arranged between the first region and an end portion of the substrate, and
wherein the forming the first film includes applying the precursor in such a manner that the application amount of the precursor is larger at the first region than on the second region.
